(19) United States
(12) Patent Application Publication
(10) Pub. No.: US 2003/0121888 A1
(43) Pub. Date: Jul. 3, 2003

(54) Etching method

(76) Inventor: Kenji Adachi, Hsin-Chu City (TW)

Correspondence Address: SMITH, GAMBRELL & RUSSELL, LLP, 1850 M STREET, N.W., SUITE 800, WASHINGTON, DC, 20036, US

(21) Appl. No.: 10/307,488

(22) Filed: Dec. 2, 2002

(30) Foreign Application Priority Data
Nov. 30, 2001 (JP) 2001-367267

(51) Int. Cl. H01L 21/3065

(52) U.S. Cl. 216/71; 216/67; 216/72; 216/79

(57) ABSTRACT

An etching method of the invention includes: an arranging step of arranging an object to be processed in a processing chamber, the object to be processed having a silicon oxide film and a silicon nitride film, the silicon oxide film being covered by the silicon nitride film; and an etching step of generating plasma of an etching gas in the processing chamber to etch the silicon nitride film of the object to be processed. A mixture gas including CH₃F gas and O₂ gas is used as the etching gas in the etching step. The essential feature of the invention is that a mixture ratio of the O₂ gas with respect to the CH₃F gas in the mixture gas (O₂/CH₃F) is set to be 4 to 9.

### BACKGROUND OF THE INVENTION

1.Field of the Invention

This invention relates to an etching method for etching a silicon nitride film covering a silicon oxide film formed on an object to be processed.

2. Description of the Related Art

In a process of forming a device on a wafer, there exists a step of dry-etching (to be simply referred to as “etching” hereinafter) a silicon nitride film (Si₃N₄ film, to be simply referred to as “SiN film” hereinafter) covering a silicon oxide film (SiO₂ film). In this etching step, for example, an etch system using plasma is widely used conventionally. As for an etching gas, a gas which etches the SiN film selectively over the SiO₂ film is required.

Conventionally, for example, CHF₃ gas or CH₂F₂ gas is known for such an etching gas. In addition, Japanese Patent Laid-open No. Hei 8-059215 proposes a nitride etching process, in which an etching gas including CHₓF₄₋ₓ(x=2 to 3) and an oxygen-containing gas is used and a sufficiently low electric power bias is selected so as to selectively etch a SiN film on a foundation layer such as a silicon oxide.

Here, the CHF₃ gas has an etching selectivity of the SiN film over the SiO₂ film (an etching rate of the SiN/an etching rate of the SiO₂ (to be simply referred to as “SiN film/SiO₂ film” hereinafter)) of not more than 5. The CH₂F₂ gas has the above etching selectivity of not more than 10.

On the other hand, in a field of a device processing, film thickness of the SiO₂ film has been decreased. Therefore, conventional etching selectivity of the SiN film over the SiO₂ film described above has become insufficient. That is, if the aforementioned etching selectivity is small, the SiO₂ film may be also removed when etching the SiN film, whereby function thereof as a device may be lost.

Furthermore, although the nitride etching process described in the above Gazette has an advantage in that the nitride etching process can be carried out with a low electric power bias, the etching selectivity thereof is about 4, which is insufficient.

### SUMMARY OF THE INVENTION

This invention is intended to solve the above problem effectively. The object of this invention is to provide an etching method having a considerably higher etching selectivity of a SiN film over a SiO₂ film (SiN film/SiO₂ film) than ever before when etching the SiN film on the SiO₂ film.

In order to achieve the above object, an etching method according to the present invention comprises: an arranging step of arranging an object to be processed in a processing chamber, the object to be processed having a silicon oxide film and a silicon nitride film, the silicon oxide film being covered by the silicon nitride film; and an etching step of generating plasma of an etching gas in the processing chamber to etch the silicon nitride film of the object to be processed; wherein a mixture gas including CH₃F gas and O₂ gas is used as the etching gas in the etching step; and a mixture ratio of the O₂ gas with respect to the CH₃F gas (O_{2/}CH₃F) in the mixture gas is set to be 4 to 9.

According to the present invention, since the mixture ratio of the O₂ gas with respect to the CH₃F gas (O_{2/}CH₃F) in the mixture gas is set to be 4 to 9, it is possible to considerably enhance the etching selectivity of the SiN film over the SiO₂ film (SiN film/SiO₂ film) than ever before when etching the SiN film on the SiO₂ film.

More preferably, the mixture ratio of the O₂ gas with respect to the CH₃F gas (O_{2/}CH₃F) in the mixture gas is set to be 4 to 6. If the upper limit of the mixture ratio is not 9 but 6, the etching selectivity of the SiN film over the SiO₂ film (SiN film/SiO₂ film) can be further enhanced.

Moreover, pressure of the etching gas is preferably set to be 50 mTorr to 200 mTorr in the etching step.

Additionally, the etching gas may further include Ar gas.

A system to carry out the etching method of the present invention is, for example, a parallel flat type etch system. In this case, in the arranging step the object to be processed is placed on a lower electrode provided in the processing chamber, and in the etching step electric field is formed between the lower electrode and an upper electrode that is opposite and parallel to the lower electrode.

At this time, it is preferable that a high-frequency electric power is applied to the lower electrode, the high-frequency electric power is set to be not more than 1.6 W/cm², and still that temperature of the lower electrode is set to be not more than 50° C.

Alternatively, it is preferable that a high-frequency electric power is applied to the upper electrode, and that the high-frequency electric power is set to be not more than 1.6 W/cm². Additionally, the plasma generated in the etching step has ion density of 1×10¹⁰ ion/cm³ to 5×10¹⁰ ion/cm³.

### BRIEF DESCRIPTION OF THE DRAWINGS

FIG. 1 is a schematic sectional view of an example of an etch system suitably used in an etching method of the present invention;

FIG. 2 is a graph depicting relationship between etching rates of a SiN film and a SiO₂ film, in-plane uniformities thereof and etching selectivity therebetween, when a flow ratio of CH₃F gas with respect to O₂ gas is set to be substantially constant while flow rates of the respective gases are changed in the etch system shown in FIG. 1; and

FIG. 3 is a graph depicting relationship between etching rates of a SiN film and a SiO₂ film, in-plane uniformities thereof and etching selectivity therebetween, when a temperature and a high-frequency electric power of a lower electrode are changed in the etch system shown in FIG. 1.

### DESCRIPTION OF THE PREFERRED EMBODIMENT

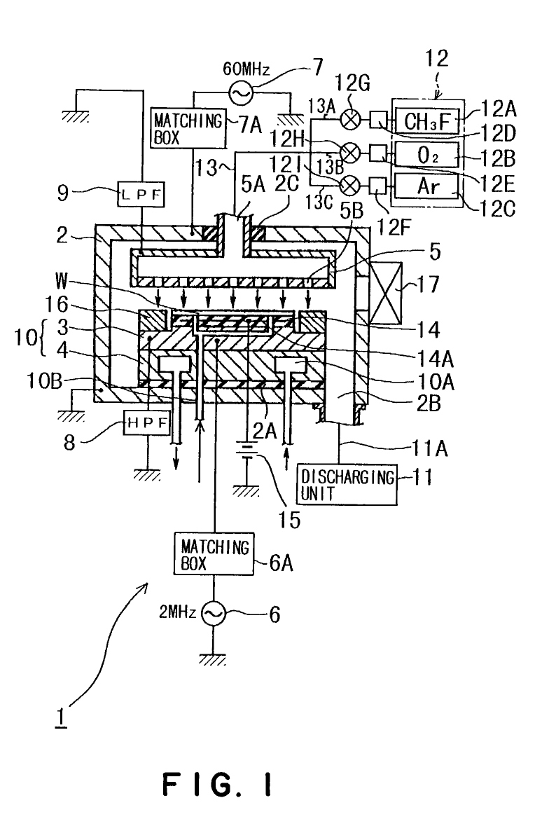

Hereinafter, an embodiment of the present invention will be explained with reference to FIG. 1 to FIG. 3.

An etch system 1 shown in FIG. 1 is provided with a processing chamber 2 capable of keeping a desired degree of high vacuum. An aluminum surface of the processing chamber 2 is processed by anodic oxide coating and electrically connected to ground. A lower electrode 3 on which an object to be processed, for example, wafer W is placed is arranged at a center of a bottom surface in the processing chamber 2. The lower electrode 3 is supported by a supporter 4, which is arranged on the bottom surface of the processing chamber 2 through an insulating member 2A. A hollow upper electrode 5 is provided to be opposite to the lower electrode 3 through a gap. To the lower electrode 3, a high-frequency electric power supply 6 of, for example, 2 MHz is connected through a matching box 6A. To the upper electrode 5, a high-frequency electric power supply 7, whose frequency is higher than that of the lower electrode 3, for example, of 60 MHz is connected through a matching box 7A. The lower electrode 3 is connected to ground through a highpass filter 8 and the upper electrode 5 is connected to ground through a lowpass filter 9. In addition, a discharging unit 11 is connected through a pipe 11A to an exhaust opening 2B formed in the bottom surface of the processing chamber 2. This discharging unit 11 is adapted to evacuate gas in the processing chamber 2, so that the chamber can keep a desired degree of vacuum. Incidentally, the lower electrode 3 and the supporter 4 are collectively referred to as a mounting table 10 in general.

A gas introducing pipe 5A is connected to a center of an upper surface of the upper electrode 5. The gas introducing pipe 5A pierces a hole of an insulating member 2C arranged at the center of the upper surface of the processing chamber 2. Then, to the gas introducing pipe 5A, a processing gas supply source 12 is connected through a pipe 13. More specifically, the processing gas supply source 12 has a CH₃F gas supply source 12A, an O₂ gas supply source 12B and an Ar gas supply source 12C. These gas supply sources 12A, 12B and 12C are respectively connected to branch passages 13A, 13B and 13C from the pipe 13. Corresponding to the CH₃F gas supply source 12A, the O₂ gas supply source 12B and the Ar gas supply source 12C, the respective branch passages 13A, 13B and 13C are provided with flow-rate control units 12D, 12E and 12F and valves 12G, 12H and 12I in this order from an upstream side thereof to a downstream side thereof. By means of these flow-rate control units 12D, 12E and 12F and valves 12G, 12H and 12I, etching gases to be supplied into the processing chamber 2 are controlled to be at predetermined flow-rates respectively.

There are many holes 5B formed evenly dispersed in a lower surface of the upper electrode 5. Through each hole 5B, the processing gas can be supplied and dispersed evenly into the processing chamber 2. Therefore, gas in the processing chamber 2 can be evacuated by the discharging unit 11 as well as a predetermined etching gas can be supplied from the processing gas supply source 12 at a predetermined flow-rate. Then, under such a condition, by applying the respective high-frequency electric power to the lower electrode 3 and the upper electrode 5, plasma of the etching gas is generated in the processing chamber 2. Thereby, a predetermined etching process is carried out to the wafer W on the lower electrode 3.

A temperature sensor (not shown) is fixed at the lower electrode 3. Temperature of the wafer W on the lower electrode 3 can be constantly monitored by means of the temperature sensor.

There is a refrigerant flow path 10A formed in the mounting table 10, through which a predetermined refrigerant (for example, well-known fluorine fluid, water, and the like) passes. When the refrigerant flows in the refrigerant flow path 10A, the lower electrode 3 is cooled and then the wafer W is cooled via the lower electrode 3. Thereby, the wafer W can be controlled to be at a desired temperature.

Additionally, there is an electrostatic chuck 14 made of an insulating material arranged above the lower electrode 3. An electrode plate 14A in the electrostatic chuck 14 is connected to a high-voltage direct current source 15. The electrostatic chuck 14 generates electrostatics on a surface thereof due to a high-voltage direct current applied from the high-voltage direct current source 15 to the electrode plate 14A, whereby the wafer W is electrostatically sucked on the surface.

A focus ring 16 is arranged at an outer peripheral edge of the lower electrode 3 in such a manner that the focus ring 16 surrounds the electrostatic chuck 14. The focus ring 16 enables the plasma to be focused on the wafer W.

On the mounting table 10, formed is a gas flow path 10B for supplying a heat conducting gas such as He gas as a backside gas. The gas flow path 10B has openings at a plurality of positions of the upper surface of the mounting table 10. Corresponding to these opening positions of the gas flow path 10B, pierced holes are also formed through the electrostatic chuck 14 above the mounting table 10. According to this structure, when the backside gas is supplied though the gas flow path 10B of the mounting table 10, this backside gas flows out from the gas flow pass 10B through the pierced holes of the electrostatic chunk 14 and diffuses evenly to the whole gap between the electrostatic chunk 14 and the wafer W. Accordingly, it is possible to enhance heat conductivity in the gap between them. Incidentally, in FIG. 1, numerical sign 17 designates a gate valve that can open and close a wafer-transferring port formed in the processing chamber 2.

Next, an embodiment of an etching method according to the present invention using the aforementioned etch system 1 will be explained.

The etching method of the embodiment is characterized in that plasma of an etching gas is generated in the processing chamber 2 and that a mixture gas including CH₃F gas and O₂ gas is used as the etching gas when etching a SiN film covering a SiO₂ film formed on the wafer W arranged in the processing chamber 2. Additionally, Ar gas is added to the aforementioned mixture gas when needed.

Now, the embodiment in which the O₂ gas and the CH₃F gas are used as the etching gas will be explained below.

First, after residual gas in the processing chamber 2 is replaced (evacuated), the gate valve 17 is opened. A wafer W on which a SiN film is formed to cover a SiO₂ film is then transferred into the processing chamber 2. After the wafer W is placed on the mounting table 10 in the processing chamber 2, the gate valve 17 is closed. The backside gas is then constantly supplied from the gas flow path 10B so as to enhance heat conductivity between the wafer W and the electrostatic chuck 14. Thus, the wafer W is efficiently cooled and controlled to be at a predetermined temperature.

Thereafter, the valves 12G and 12H corresponding to the CH₃F gas supply source 12A and the O₂ gas supply source 12B are opened. A flow rate of the mixture gas of the CH₃F gas and the O₂ gas is controlled by the respective flow control units 12D and 12E, and pressure of the mixture gas in the processing chamber 2 is controlled by means of the discharging unit 11.

Here, when a flow ratio of the O₂ gas with respect to the CH₃F gas (O_{2/}CH₃F) is less than 4, depositions of CF series can be easily formed on the SiN film due to increase in the ratio of the CH₃F gas, so that there is a possibility that the etching process can be stopped due to the influence of the depositions. On the other hand, when the flow ratio of the O₂ gas with respect to the CH₃F gas (O_{2/}CH₃F) is more than 9, there is another possibility that an etching rate of the SiN film is decreased and that the etching selectivity of the SiN film over the SiO₂ film (SiN film/SiO₂ film) is decreased. Therefore, in this embodiment, the mixture ratio (flow ratio) of the O₂ gas with respect to the CH₃F gas, O_{2/}CH₃F, is set to be 4 to 9. Moreover, it is more preferable that the flow ratio of the O₂ gas with respect to the CH₃F gas (O_{2/}CH₃F) is set to be 4 to 6. By changing the upper limit of the flow ratio from 9 to 6, it is possible to further enhance the etching selectivity of the SiN film over the SiO₂ film.

In addition, the pressure of the mixture gas of the O₂ gas and the CH₃F gas in the processing chamber 2 is preferably set to be 50 mTorr to 200 mTorr, much preferably set to be 50 mTorr to 100 mTorr in particular. When the pressure of the mixture gas becomes less than 50 mTorr, there is a possibility that the etching process can be stopped due to the influence of the depositions on the SiN film. On the other hand, when the pressure of the mixture gas becomes more than 200 mTorr, there is another possibility that the etching rate of the SiN film is decreased and then the etching selectivity of the SiN film over the SiO₂ film (SiN film/SiO₂ film) is also decreased.

Furthermore, by properly adding the Ar gas, which has a property to accelerate CH₃F dissociation, to the above mixture gas, it is possible to further adjust the etching rate of the SiN film.

After the flow rate and the pressure of the above mixture gas are controlled to be in the above range, the respective high-frequency electric power is applied to the lower electrode 3 and the upper electrode 5. By the high-frequency electric power of 60 MHz applied to the upper electrode 5, plasma of the mixture gas is generated. On the other hand, by the high-frequency electric power of 2 MHz applied to the lower electrode 3, bias potential is generated at the wafer W. By a potential difference between the plasma potential and the bias potential, etching of the SiN film is accelerated.

At this time, when a wafer having a diameter of 200 mm is etched, the high-frequency electric power of the lower electrode 3 is preferably set to be not more than 500 W, much preferably set to be 0 W to 300 W in particular. A surface temperature on the wafer W is preferably set to be 20° C. to 80° C. In order to achieve the surface temperature of 20° C. to 80° C., a temperature of the lower electrode 3 is set to be not more than 50° C., preferably set to be 20° C. to 40° C. in particular. Still more, when a wafer having a diameter of 200 mm is etched, the high-frequency electric power of the upper electrode 5 is preferably set to be not more than 500 W, much preferably set to be 0 W to 300 W in particular. By setting the electric power of the upper electrode 5 to be not more than 500W, ion density of the plasma can be controlled to be 1×10¹⁰ ion/cm³ to 5×10¹⁰ ion/cm³. Consequently, the SiN film can be etched with an excellent etching selectivity and an in-plane uniformity. When the ion density is apart from the above range, the etching selectivity may be decreased or the etching process may not proceed.

Incidentally, in a case wherein a wafer has a diameter of 200 mm, the most suitable set value for the high-frequency electric power is mentioned above. However, in a case wherein a wafer has a diameter of 300 mm, those of both upper and lower electrodes are preferably set to be not more than 1200 W, much preferably set to be 0 to 700 W in particular. In other words, in accordance with a size of a wafer to be processed, those of both upper and lower electrodes are preferably set to be not more than 1.6 W/cm², much preferably set to be 0 to 1.0 W/cm² in particular.

When the SiN film is etched under the aforementioned condition, the etching selectivity of the SiN film over the SiO₂ film becomes at least 10 or more, in many cases 20 or more. That is, etching can be prevented from stopping under the influence of the depositions as well as a considerably higher etching selectivity than ever before can be achieved. Therefore, even when thickness of a SiO₂film composing a device is made decreased, it is possible to prevent the SiO₂ film from being removed while etching the SiN film, namely to prevent SiO₂ break from occurring. Therefore, it is possible to etch only the SiN film with secure and to produce a device having superior electrical properties.

### <EXAMPLES>

In examples shown below, wafers on whose surfaces SiN films had been formed and wafers on whose surfaces SiO₂ films had been formed were used. The respective wafers were etched separately by the etching method of the invention. Etching rates and etching in-plane uniformities of the respective SiN films and SiO₂ films were measured. Based on these measurements, etching selectivities (SiN film/SiO₂ film) were obtained by using ratios of the etching rates of the SiN film with respect to those of the SiO₂ film. Hereinafter, each example will be explained in detail below.

### <Example 1 to 4>

In these examples, SiN films and SiO₂ films were etched based on the following etching condition while a pressure of a mixture gas of CH₃F gas and O₂ gas in the processing chamber 2, electric power of the upper electrode 5, and a flow rate of the CH₃F gas were respectively changed as shown in Table. 1. The respective measurements of the etching rates and the etching in-plane uniformities are shown in Table. 2. As shown in Table. 2, in these examples, the etching selectivities were obtained at the minimum 11.85 and at the maximum 20.75.

[Fundamental Etching Condition]

1. pressure of a mixture gas : 50 mTorr

2. electric power of high-frequency electric power (T/B) 500 W/100 W

(T designates a top (upper) electrode, and B designates a bottom (lower) electrode. The same symbols also designate the same below.)

3. distance between the upper electrode and the lower electrode : 45mm

4. flow ratio of the mixture gas (CH₃F/O₂): 35/200 sccm

5. pressure of a backside gas (C/E) : 10/35 Torr

(C designates a center portion of a mounting table, and E designates an edge portion of the mounting table. The same symbols also designate the same below.)

6. temperature of each portion (B/T/W) : 20/60/50° C.

(B designates the bottom (lower) electrode, and T designates the top (upper) electrode, and W designates an inner peripheral face of the processing chamber. The same symbols also designate the same below.)

7. diameter of a wafer to be used : 200 mm

TABLE 1

| | pressure | electric power of | CH₃F flow |
|---|---|---|---|
| | (Torr) | upper electrode (w) | rate (sccm) |
| Example 1 | 50 | 100 | 25 |
| Example 2 | 50 | 500 | 35 |
| Example 3 | 100 | 100 | 35 |
| Example 4 | 100 | 500 | 25 |

TABLE 2

| | | in-plane | E/R | in-plane | |
|---|---|---|---|---|---|
| | E/R of | uniformity | of | uniformity | |
| | nitride | of nitride | oxide | of oxide | etching |
| | film | film | film | film | selectivity |
| Example | 454.2 | 10.1 | 26.82 | 78.4 | 16.94 |
| 1 | | | | | |
| Example | 889.1 | 21.6 | 49.2 | 40.6 | 18.07 |
| 2 | | | | | |
| Example | 493.9 | 2.8 | 23.8 | 25.3 | 20.75 |
| 3 | | | | | |
| Example | 618.5 | 8.2 | 52.2 | 21.1 | 11.85 |
| 4 | | | | | |

Note that the E/R in the table 2 indicates the etching rate in unit of Angstrom/minute. The in-plane uniformity indicates a calculation result of (maximum value−minimum value)/(means×2)×100″ obtained from a plurality of points on the wafer.

### <Examples 5 to 8>

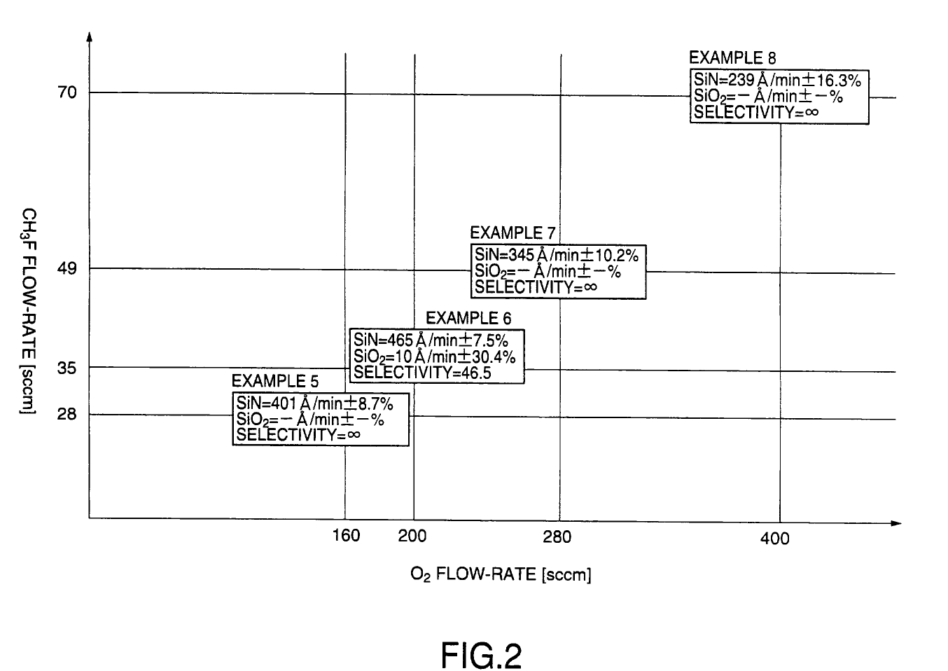

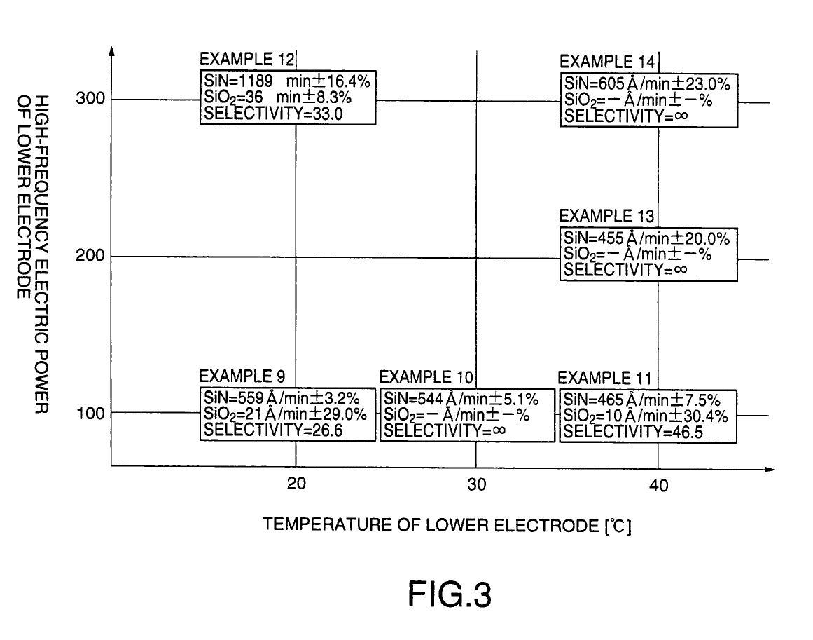

In these examples, under the following condition, SiN films and SiO₂ films were etched while the flow ratio of the O₂ gas with respect to the CH₃F gas (O_{2/}CH₃F) was kept substantially constant at 5.7 and the respective flow rates were set to be 160 sccm/28 sccm, 200 sccm/35 sccm, 280 sccm/49 sccm, and 400 sccm/70 sccm. Then, the respective etching rates and the in-plane uniformities were measured. The respective results are shown in FIG. 2. As shown in FIG. 2, the etching selectivities of at the minimum 46.5 can be obtained in these examples. Incidentally, in FIG. 2, the etching rates and the in-plane uniformities of the SiO₂ films in some examples are shown by a sign “−”, because the SiO₂ films were hardly etched, so that the etching rates and the in-plane uniformities of the SiO₂ films could not be measured. Additionally, in FIG. 2, the etching selectivities of the examples where the SiO₂ films are hardly etched were shown as infinity “∝” for the sake of convenience. The same is also shown in FIG. 3 below.

[Etching Condition]

1. pressure of a mixture gas : 100 mTorr

2. electric power of high-frequency electric power (T/B):100 W/100 W

3. distance between an upper electrode and a lower electrode: 45mm

4. pressure of a backside gas (C/E) : 10/35 Torr

5. temperature of each portion (B/T/W) : 40/60/50° C.

6. diameter of a wafer to be used : 200 mm

### <Examples 9 to 14>

In these examples, under the following condition, while temperature of a lower electrode and a high-frequency electric power were respectively changed as shown in FIG. 3, SiN films and SiO₂ films were etched. The respective results of etching rates and in-plane uniformities are shown in FIG. 3. As shown in FIG. 3, in these examples, the etching selectivities of at the minimum 26.6 could be obtained.

[Etching Condition]

1. pressure of a mixture gas: 100 mTorr

2. electric power of high-frequency electric power of an upper electrode: 100 W

3. distance between the upper electrode and a lower electrode: 45mm

4. flow rate of the mixture gas (CH₃F/O₂): 35/200 sccm

5. pressure of a backside gas (C/E): 10/35 Torr

6. temperature of each portion (T/W) : 60/50° C.

7. diameter of a wafer to be used : 200 mm

As described above, the plasma of the etching gas is generated in the processing chamber 2 in the parallel-flat type of etch system 1, and a silicon nitride film covering a silicon oxide film formed on a wafer arranged on the lower electrode 3 in the etch system 1 is etched. At this time, the mixture gas of the O₂ gas and the CH₃F gas is used as the etching gas, and the flow ratio of the O₂ gas with respect to the CH₃F gas (O_{2/}CH₃F) in the mixture gas is set to be 4 to 9. Thereby, the etching selectivity of the SiN film over the SiO₂ film becomes at least 10 or more, in many cases 20 or more. That is, as compared with conventional cases, it is possible to prevent the etching step from stopping due to influence of depositions and to enhance the etching selectivity considerably. Therefore, even if film thickness of the SiO₂ film composing a device is decreased much, break of the SiO₂ film can be prevented and only the SiN film can be etched selectively. Therefore, a device having superior electrical properties can be obtained. Still further, it is possible to further enhance the etching selectivity of the SiN film over the SiO₂ film by setting the flow ratio of the O₂ gas with respect to the CH₃F gas (O_{2/}CH₃F ) to be 4 to 6.

Additionally, as described above, the plasma having ion density of 1×10¹⁰ ion/cm³ to 5×10¹⁰ ion/cm³ is generated by setting the pressure of the mixture gas of the O₂ gas and the CH₃F gas in the processing chamber 2 to be 50 mTorr to 200 mTorr, setting the lower electrode 3 to be not more than 1.6 W/cm² in accordance with a size of a wafer to be processed and the temperature of the lower electrode 3 to be not higher than 50° C., and further setting the high-frequency electric power of the upper electrode 5 to be not more than 1.6 W/cm² in accordance with the size of a wafer to be processed. Accordingly, it is possible to prevent the etching process from stopping due to influence of depositions, as well as to obtain a high etching selectivity without fail. In addition, by adding the Ar gas to the mixture gas of the O₂ gas and the CH₃F gas, it is possible to keep the aforementioned etching selectivity as well as to enhance the etching rate of the SiN film.

Note that this invention should not be limited to the aforementioned embodiments at all. For example, while the etch system in which high-frequency electric power is applied to both of the upper and lower electrodes 3 and 5 is used as an example to explain the above embodiments, the present invention can also be applied to a parallel-flat type of etch system in which a high-frequency electric power is applied to a lower electrode and an upper electrode is connected to the ground. Also, the object to be processed should not be limited to the wafer.

1. An etching method comprising:
an arranging step of arranging an object to be processed in a processing chamber, the object to be processed having a silicon oxide film and a silicon nitride film, the silicon oxide film being covered by the silicon nitride film; and
an etching step of generating plasma of an etching gas in the processing chamber to etch the silicon nitride film of the object to be processed;
wherein
a mixture gas including CH₃F gas and O₂ gas is used as the etching gas, in the etching step; and
a mixture ratio of the O₂ gas with respect to the CH₃F gas in the mixture gas (O_{2/}CH₃F) is set to be 4 to 9.

2. An etching method according to claim 1, wherein
the mixture ratio of the O₂ gas with respect to the CH₃F gas in the mixture gas (O_{2/}CH₃F) is set to be 4 to 6.

3. An etching method according to claim 1, wherein
a pressure of the etching gas is set to be 50 mTorr to 200 mTorr in the etching step.

4. An etching method according to claim 1, wherein
the etching gas further includes Ar gas.

5. An etching method according to claim 1, wherein
the object to be processed is placed on a lower electrode provided in the processing chamber, in the arranging step; and
electric field is formed between the lower electrode and an upper electrode that is opposite and parallel to the lower electrode, in the etching step.

6. An etching method according to claim 5, wherein
in the etching step, a high-frequency electric power is applied to the lower electrode, the high-frequency electric power is set to be not more than 1.6 W/cm², and temperature of the lower electrode is set to be not more than 50° C.

7. An etching method according to claim 5, wherein
in the etching step, a high-frequency electric power is applied to the upper electrode, and the high-frequency electric power is set to be not more than 1.6 W/cm².

8. An etching method according to claim 1, wherein
the plasma generated in the etching step has ion density of 1×10¹⁰ ion/cm³ to 5×10¹⁰ ion/cm³.
